(19) United States
(12) Patent Application Publication
(10) Pub. No.: US 2016/0079110 A1
(43) Pub. Date: Mar. 17, 2016

(54) SEMICONDUCTOR PACKAGE, CARRIER STRUCTURE AND FABRICATION METHOD THEREOF

(71) Applicant: Siliconware Precision Industries Co., Ltd., Taichung (TW)

(72) Inventors: Kuan-Wei Chuang, Taichung (TW); Shih-Kuang Chiu, Taichung (TW); Chun-Tang Lin, Taichung (TW); Jung-Pang Huang, Taichung (TW)

(21) Appl. No.: 14/849,639

(22) Filed: Sep. 10, 2015

(30) Foreign Application Priority Data
Sep. 15, 2014 (TW) 103131713

(51) Int. Cl. H01L 21/683; H01L 21/56; H01L 23/00; H01L 23/31; H01L 23/528

(52) U.S. Cl. CPC H01L 21/6835; H01L 23/3107; H01L 23/528; H01L 24/96; H01L 21/568; H01L 2221/68327; H01L 2221/68359

(57) ABSTRACT

A semiconductor package is provided, which includes: a carrier; a frame having a plurality of openings, wherein the frame is bonded to the carrier and made of a material different from that of the carrier; a plurality of electronic elements disposed in the openings of the frame, respectively; an encapsulant formed in the openings of the frame for encapsulating the electronic elements; and a circuit layer formed on and electrically connected to the electronic elements. By accurately controlling the size of the openings of the frame, the present invention increases the accuracy of positioning of the electronic elements so as to improve the product yield in subsequent processes.

### BACKGROUND OF THE INVENTION

1. Field of the Invention The present invention relates to semiconductor packages, and more particularly, to a semiconductor package and a fabrication method thereof for improving the product yield.

2. Description of Related Art

Along with the rapid development of electronic industries, electronic products are developed toward the trend of multi-function and high performance. Accordingly, wafer level packaging (WLP) technologies have been developed to meet the miniaturization requirement of semiconductor packages.

FIGS. 1A to 1E are schematic cross-sectional views showing a method for fabricating a wafer level semiconductor package 1 according to the prior art.

Referring to FIG. 1A, a thermal release tape 11 is formed on a carrier 10, and then a plurality of semiconductor elements 12 are disposed on the thermal release tape 11. Each of the semiconductor elements 12 has an active surface 12a with a plurality of electrode pads 120 and an inactive surface 12b opposite to the active surface 12a. The semiconductor elements 12 are attached to the thermal release tape 11 via the active surfaces 12a thereof.

Referring to FIG. 1B, an encapsulant 13 made of such as a molding compound is formed on the thermal release tape 11 for encapsulating the semiconductor elements 12, and the inactive surfaces 12b of the semiconductor elements 12 are exposed from the encapsulant 13.

Referring to FIG. 1C, a support member 17 is attached to the encapsulant 13 and the inactive surfaces 12b of the semiconductor elements 12 through a bonding layer 170, and then the thermal release tape 11 and the carrier 10 are removed to expose the active surfaces 12a of the semiconductor elements 12.

Referring to FIG. 1D, an RDL (redistribution layer) process is performed. Thus, an RDL structure 14 is formed on the encapsulant 13 and the active surfaces 12a of the semiconductor elements 12 and electrically connected to the electrode pads 120 of the semiconductor elements 12.

Then, an insulating layer 15 is formed on the RDL structure 14, and portions of the surface of the RDL structure 14 are exposed from the insulating layer 15 for mounting a plurality of solder balls 16.

Referring to FIG. 1E, a singulation process is performed along a cutting path S of FIG. 1D and the support member 17 and the bonding layer 170 are removed. As such, a plurality of semiconductor packages 1 are obtained.

However, when the molding compound is injected into a mold to form the encapsulant 13, a lateral force generated by flow of the molding compound may adversely affect the accuracy of positioning of the semiconductor elements 12. For example, the semiconductor elements 12 are easily displaced from their predetermined positions on the thermal release tape 11. As such, an alignment deviation occurs between the RDL structure 14 and the electrode pads 120 of the semiconductor elements 12 and consequently, the electrical connection between the RDL structure 14 and the electrode pads 120 of the semiconductor elements 12 is adversely affected, thus reducing the product yield and reliability.

To overcome the above-described drawbacks, another method for fabricating a semiconductor package 2 is provided, as shown in FIGS. 2A to 2E. Referring to FIG. 2A, a plurality of openings 200 are formed on a carrier 20 through a sandblasting process. The sandblasting process involves forming a patterned resist layer (not shown) on the carrier 20 and then blasting abrasive particles toward the moving carrier 20 with high pressure air. As such, portions of the carrier 20 exposed from the patterned resist layer are etched by the abrasive particles to form the openings 200.

Referring to FIG. 2B, a plurality of semiconductor elements 22 are disposed in the openings 200 through an adhesive layer 21. Each of the semiconductor elements 22 has an active surface 22a with a plurality of electrode pads 220 and an inactive surface 22b opposite to the active surface 22a, and the semiconductor element 22 is attached to the adhesive layer 21 via the inactive surface 22b thereof.

Referring to FIG. 2C, an encapsulant 23 is formed in the openings 220 and on the semiconductor elements 22, and an RDL structure 24 is formed on the encapsulant 23 and electrically connected to the electrode pads 220 of the semiconductor elements 22. Then, an insulating layer 25 is formed on the RDL structure 24, and portions of the surface of the RDL structure 24 are exposed from the insulating layer 25 for mounting a plurality of solder balls 26.

As such, the semiconductor elements 22 are positioned in the openings 200 of the carrier so as to be protected from being adversely affected by a lateral force generated by flow of the material of the encapsulant 23, thereby overcoming the above-described drawback of alignment deviation between the RDL structure 24 and the electrode pads 220 of the semiconductor elements 22.

Referring to FIG. 2D, a portion of the carrier 20 below the openings 200 and the adhesive layer 21 are removed.

Referring to FIG. 2E, a singulation process is performed along a cutting path S of FIG. 2D.

However, during the sandblasting process, a chamfer R will be formed at the bottom of the openings 200. Since the accuracy of the chamfer R is difficult to control, the size of the openings 200 cannot be accurately controlled, thus adversely affecting the accuracy of positioning of the semiconductor elements 22 in the openings 200. For example, the semiconductor elements 22 may be disposed obliquely in the openings 200, as shown in FIG. 2B′. As such, referring to FIG. 2E′, it becomes impossible to establish an electrical connection between the RDL structure 24 and the electrode pads 220 of the semiconductor elements 22. Further, a corner defect K is formed on the surface of the semiconductor package 2, which adversely affects the product yield in subsequent processes.

Therefore, how to overcome the above-described drawbacks has become critical.

### SUMMARY OF THE INVENTION

In view of the above-described drawbacks, the present invention provides a semiconductor package, which comprises: a carrier; a frame having a plurality of openings, wherein the frame is bonded to the carrier and made of a material different from that of the carrier; a plurality of electronic elements disposed in the openings of the frame, respectively; an encapsulant formed in the openings of the frame for encapsulating the electronic elements; and a circuit layer formed on and electrically connected to the electronic elements.

In the above-described semiconductor package, the frame can be bonded to the carrier through a bonding layer.

The present invention provides another semiconductor package, which comprises: a carrier; a frame having a plurality of openings, wherein the frame is bonded to the carrier through a bonding layer and the frame is made of the same material as the carrier; a plurality of electronic elements disposed in the openings of the frame, respectively; an encapsulant formed in the openings of the frame for encapsulating the electronic elements; and a circuit layer formed on and electrically connected to the electronic elements.

In the above-described two semiconductor packages, the carrier can be made of an inorganic material or an organic material.

The present invention provides a further semiconductor package, which comprises: a carrier made of a dielectric material; a frame having a plurality of openings, wherein the frame is bonded to and integrally formed with the carrier; a plurality of electronic elements disposed in the openings of the frame, respectively; an encapsulant formed in the openings of the frame for encapsulating the electronic elements; and a circuit layer formed on and electrically connected to the electronic elements.

In the above-described semiconductor package, the openings can have sloped sidewalls relative to the carrier.

In the above-described three semiconductor packages, the carrier can have a rectangular shape or a circular shape. In an embodiment, no chamfer is formed between the openings and the carrier.

The above-described three semiconductor packages can further comprise an RDL structure formed on the electronic elements and the circuit layer and electrically connected to the circuit layer.

The present invention further provides a method for fabricating a semiconductor package, which comprises the steps of: forming on a carrier a frame having a plurality of openings; disposing a plurality of electronic elements in the openings of the frame, respectively; forming an encapsulant in the openings of the frame for encapsulating and fixing the electronic elements; and forming a circuit layer on and electrically connected to the electronic elements.

In the above-described method, the carrier can be made of an inorganic material or an organic material, and the frame can be made of a dielectric material.

In the above-described method, the frame can be made of an inorganic material or an organic material.

In an embodiment, forming the frame comprises: disposing the carrier in a mold; filling the dielectric material in the mold to form the frame of the dielectric material; and removing the mold.

In another embodiment, forming the frame comprises: filling the dielectric material in a mold to form the frame of the dielectric material; and removing the mold.

In the above-described method, the frame can be bonded to the carrier through a bonding layer.

The present invention provides another method for fabricating a semiconductor package, which comprises the steps of: providing a carrier structure having a carrier and a frame defined therein, wherein the carrier and the frame are integrally formed and the frame has a plurality of openings; disposing a plurality of electronic elements in the openings of the frame, respectively; forming an encapsulant in the openings of the frame for encapsulating and fixing the electronic elements; and forming a circuit layer on and electrically connected to the electronic elements.

In an embodiment, fabricating the carrier structure comprises: providing a mold having a plurality of protruding portions therein; filling a dielectric material in the mold to form the carrier structure of the dielectric material, wherein the openings of the frame are formed corresponding in position to the protruding portions of the mold; and removing the mold.

In another embodiment, fabricating the carrier structure comprises: providing a mold having a plurality of protruding portions therein; filling a dielectric material in the mold; pressing the mold to form the carrier structure of the dielectric material, wherein the openings of the frame are formed corresponding in position to the protruding portions of the mold; and removing the mold.

In the above-described method, sidewalls of the openings can be sloped relative to bottom surfaces of the openings.

In the above-described two methods for fabricating a semiconductor package, the carrier can have a rectangular shape or a circular shape. In an embodiment, no chamfer is formed between the openings and the carrier.

The above-described two methods can further comprise forming an RDL structure on the electronic elements and the circuit layer, wherein the RDL structure is electrically connected to the circuit layer.

The above-described two methods can further comprise removing the carrier.

The present invention further provides a carrier structure, which comprises: a carrier; and a frame having a plurality of openings, wherein the frame is bonded to the carrier and made of a material different from that of the carrier.

In the above-described carrier structure, the frame can be bonded to the carrier through a bonding layer.

The present invention provides another carrier structure, which comprises: a carrier; and a frame having a plurality of openings, wherein the frame is bonded to the carrier through a bonding layer and the frame is made of the same material as the carrier.

In the above-described two carrier structures, the carrier can be made of an inorganic material or an organic material.

The present invention provides a further carrier structure, which comprises: a carrier made of a dielectric material; and a frame having a plurality of openings, wherein the frame is bonded to and integrally formed with the carrier.

In the above-described carrier structure, the openings can have sloped sidewalls relative to the carrier.

In the above-described three carrier structures, the carrier can have a rectangular shape or a circular shape. In an embodiment, no chamfer is formed between the openings and the carrier.

The present invention further provides a method for fabricating a carrier structure, which comprises the steps of: disposing a carrier in a mold; filling a dielectric material in the mold to form a frame of the dielectric material, wherein the frame is bonded to the carrier and has a plurality of openings; and removing the mold.

The present invention further provides a method for fabricating a carrier structure, which comprises the steps of: filling a dielectric material in a mold to form a frame of the dielectric material, wherein the frame has a plurality of openings; removing the mold; and bonding the frame to a carrier. The frame can be bonded to the carrier through a bonding layer.

In the above-described two methods, the carrier can be made of an inorganic material or an organic material.

The present invention provides a further method for fabricating a carrier structure, which comprises integrally forming a carrier and a frame bonded to the carrier through a molding process, wherein the frame has a plurality of openings.

In an embodiment, integrally forming the carrier and the frame comprises: providing a mold having a plurality of protruding portions therein; filling a dielectric material in the mold so as to cause the dielectric material to form the carrier and the frame bonded to the carrier, wherein the openings of the frame are formed corresponding in position to the protruding portions of the mold; and removing the mold.

In another embodiment, integrally forming the carrier and the frame comprises: providing a mold having a plurality of protruding portions therein; filling a dielectric material in the mold; pressing the mold so as to cause the dielectric material to form the carrier and the frame bonded to the carrier, wherein the openings of the frame are formed corresponding in position to the protruding portions of the mold; and removing the mold.

In the above-described method, the openings can have sloped sidewalls relative to the carrier.

In the above-described three methods for fabricating a carrier structure, the carrier can have a rectangular shape or a circular shape. In an embodiment, no chamfer is formed between the openings and the carrier.

Therefore, by accurately controlling the size of the openings of the frame, the present invention increases the accuracy of positioning of the electronic elements and improves the surface integrity of the semiconductor package, thereby improving the product yield in subsequent processes.

### BRIEF DESCRIPTION OF DRAWINGS

FIGS. 1A to 1E are schematic cross-sectional view showing a method for fabricating a semiconductor package according to the prior art;

FIGS. 2A to 2E are schematic cross-sectional views showing another method for fabricating a semiconductor package according to the prior art, wherein FIGS. 2B′ and 2E′ show practical structures of FIGS. 2B and 2E, respectively;

FIGS. 3A to 3F are schematic cross-sectional views showing a method for fabricating a semiconductor package according to a first embodiment of the present invention, wherein FIGS. 3C′, 3E′ and 3F′ show another embodiment of FIGS. 3C to 3F, and FIGS. 3D′ and 3D″ are schematic upper views showing different embodiments of FIG. 3D (omitting the circuit layer);

FIGS. 4A to 4F are schematic cross-sectional views showing a method for fabricating a semiconductor package according to a second embodiment of the present invention;

FIGS. 5A to 5D are schematic cross-sectional views showing a method for fabricating a semiconductor package according to a third embodiment of the present invention; and

FIGS. 6A to 6E are schematic cross-sectional views showing a method for fabricating a semiconductor package according to a fourth embodiment of the present invention, wherein FIGS. 6A′ and 6E′ show other embodiments of FIGS. 6A and 6E, respectively.

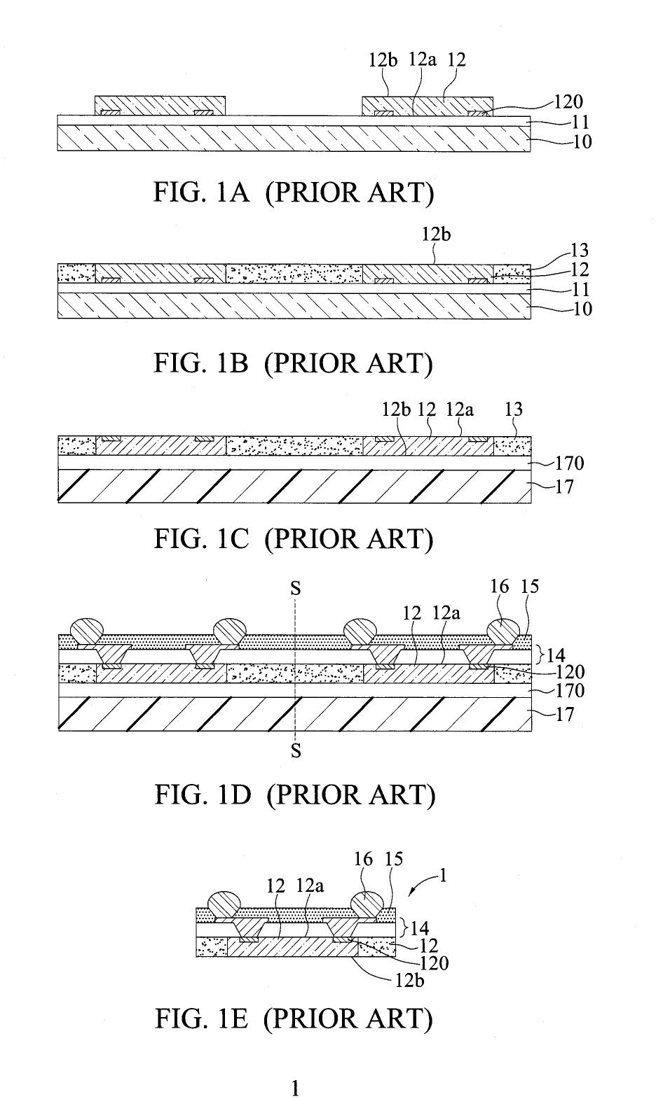

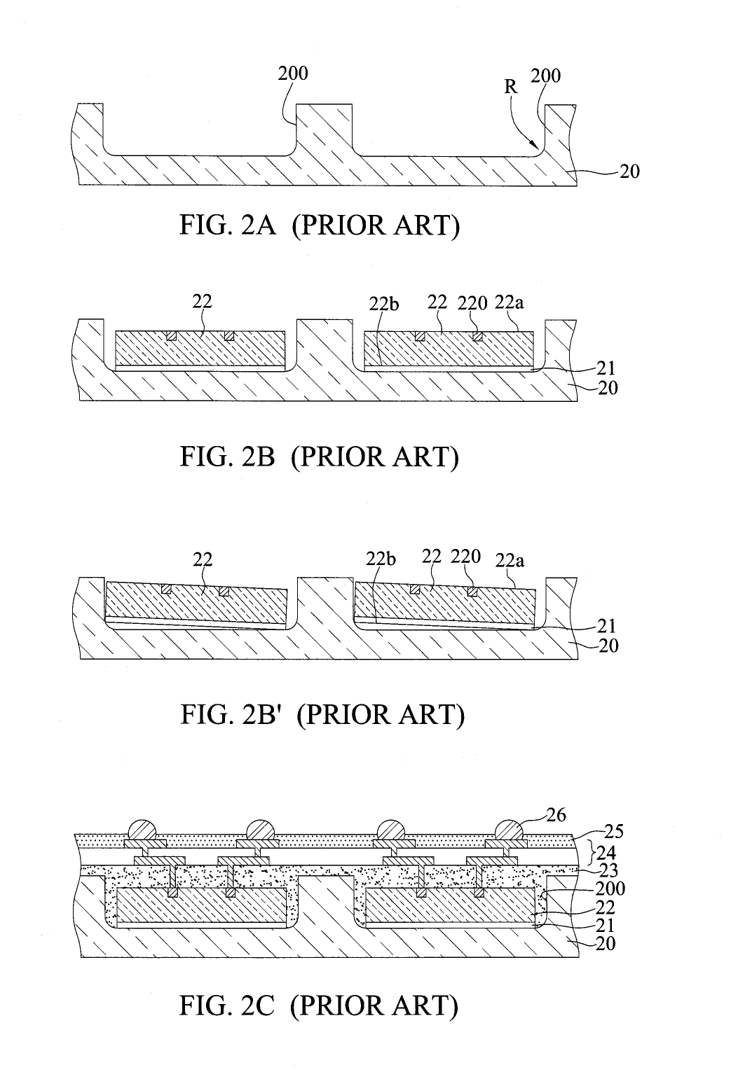

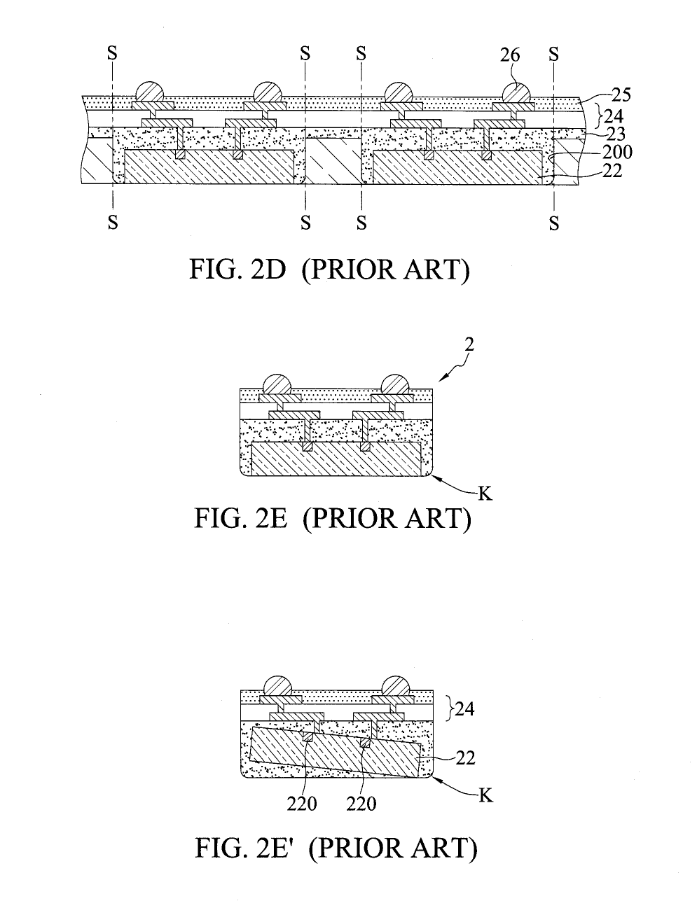

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “on”, “a” etc. are merely for illustrative purposes and should not be construed to limit the scope of the present invention.

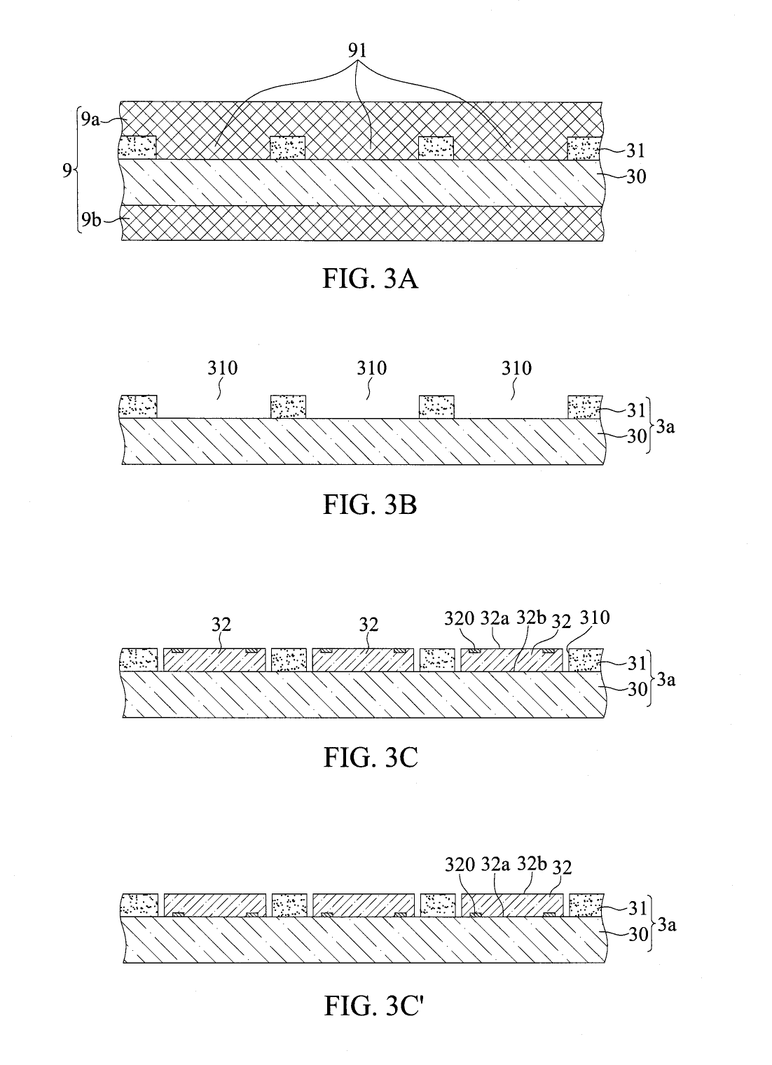

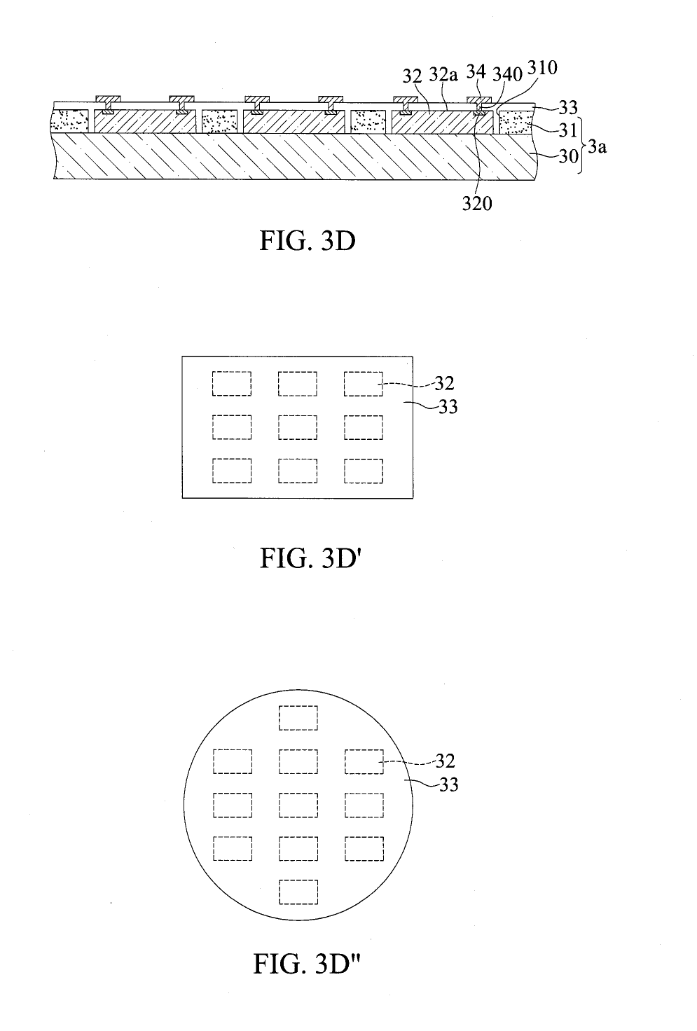

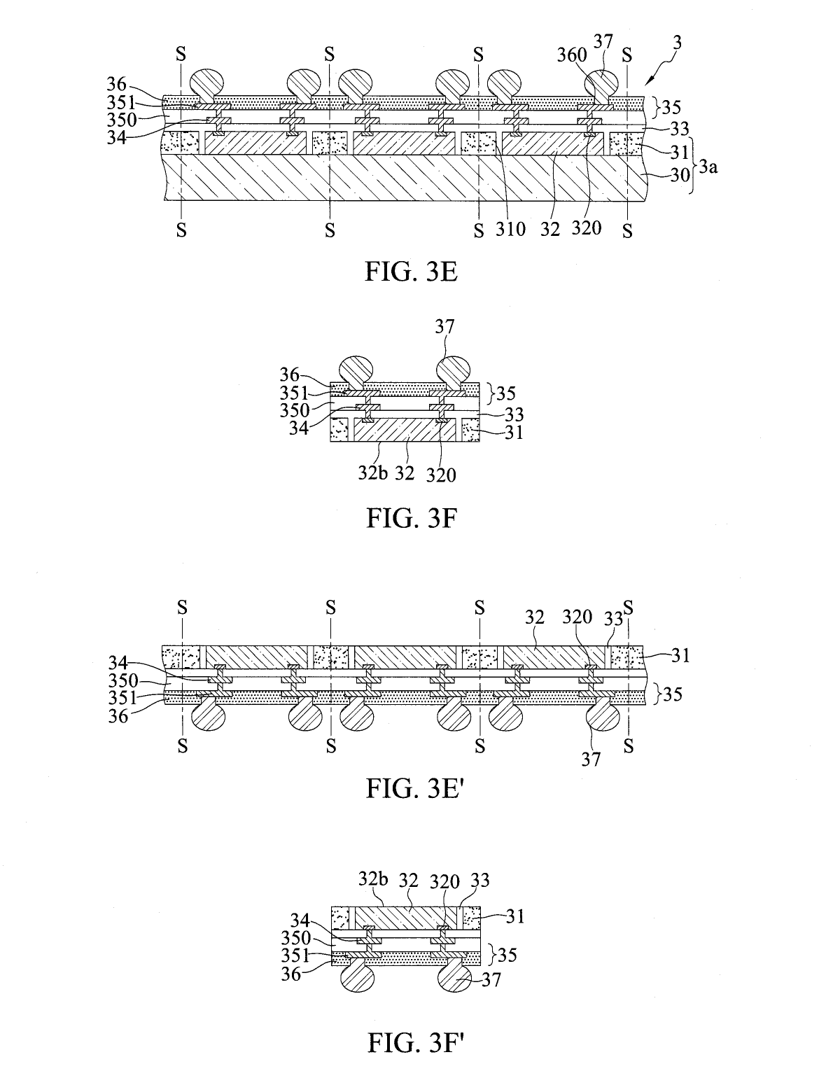

FIGS. 3A to 3F are schematic cross-sectional views showing a method for fabricating a semiconductor package 3 according to a first embodiment of the present invention. The method of the present embodiment is performed on a wafer or full panel level.

Referring to FIGS. 3A and 3B, a carrier 30 is disposed in a mold 9. Then, a dielectric material is filled in the mold 9 to form a frame 31 of the dielectric material. Then, the mold 9 is removed. As such, a frame 31 having a plurality of openings 310 is formed on the carrier 30. The frame 31 having the openings 310 and the carrier 30 constitute a carrier structure 3a.

In the present embodiment, the carrier 30 is made of an inorganic material such as a semiconductor material or ceramic, or a flexible organic material. The carrier 30 of an inorganic material is, for example, a silicon-containing substrate such as a glass board. The organic material is, for example, polyimide (PI), polybenzoxazole (PBO), benzocyclobutene (BCB) and so on.

The dielectric material of the frame 21 is made of Si, SiO₂, SiₓN_{y} and so on.

The mold 9 has a first mold body 9a and a second mold body 9b. A frame pattern 91 is formed in the first mold body 9a, and the carrier 30 is disposed on the second mold body 9b.

Referring to FIG. 3C, a plurality of semiconductor elements 32 are disposed in the openings 310 of the frame 31, respectively.

Each of the electronic elements 32 can be an active element such as a semiconductor chip, a passive element such as a resistor, a capacitor or an inductor, or a combination thereof. In the present embodiment, each of the electronic elements 32 is an active element, which has an active surface 32a with a plurality of electrode pads 320 and an inactive surface 32b opposite to the active surface 32a. The electronic elements 32 are disposed in the openings 310 via the inactive surfaces 32b thereof.

Further, the electronic elements 32 can be disposed in the openings 310 through a bonding layer (not shown). In particular, the bonding layer is a die attach film. The bonding layer can be formed on the inactive surfaces 32b of the electronic elements 32 first and then the electronic elements 32 are disposed in the openings 310 through the bonding layer. Alternatively, the bonding layer can be formed in the openings 310 by such as dispensing and then the electronic elements 32 are disposed in the openings 310 through the bonding layer.

In another embodiment, referring to FIG. 3C′, the electronic elements 32 are disposed in the openings 310 via the active surfaces 32a thereof.

Referring to FIG. 3D, continued from FIG. 3C, an encapsulant 33 is formed in the openings 310 and on the frame 31 for encapsulating and fixing the electronic elements 32. Then, a circuit layer 34 is formed on the encapsulant 33, and a plurality of conductive vias 340 are formed in the encapsulant 33 for electrically connecting the circuit layer 34 and the electrode pads 320 of the electronic elements 32.

In the present embodiment, the encapsulant 33 encapsulates the peripheral sides and the active surfaces 32a of the electronic elements 32.

The encapsulant 33 can be made of an inorganic material such as SiO₂ or SiₓN_{y}, or an organic material such as polyimide (PI), polybenzoxazole (PBO) or benzocyclobutene (BCB).

The carrier 30 can have a rectangular shape, as shown in FIG. 3D′, or have a circular shape, as shown in FIG. 3D″.

Referring to FIG. 3E, an RDL process is performed. As such, an RDL structure 35 is formed on the encapsulant 33 and the circuit layer 34 and electrically connected to the circuit layer 34.

In the present embodiment, the RDL structure 35 has a dielectric layer 350, a circuit layer 351 formed on the dielectric layer 350, and an insulating layer 36 such as a solder mask layer or a dielectric layer formed on the dielectric layer 350 and the circuit layer 351. The circuit layer 351 is electrically connected to the circuit layer 34. A plurality of openings 360 are formed in the insulating layer 36 for exposing portions of the circuit layer 351. As such, a plurality of conductive elements 37 such as solder balls can be mounted on the exposed portions of the circuit layer 351.

The dielectric layer 350 can be made of the same material as the encapsulant 33. Referring to FIG. 3F, the carrier 30 is removed to expose the inactive surfaces 32b of the electronic elements 32 and a singulation process is performed along a cutting path S of FIG. 3E. As such, a plurality of semiconductor packages 3 are obtained. It should be noted that the frame 31 is left in the packages 3 to support the overall structure and increase the rigidity of the overall structure.

Further, if the process is continued from FIG. 3C′, after the encapsulant 33 is formed (the encapsulant 33 on the inactive surfaces 32b of the electronic elements 32 can be retained or removed according to the practical need), the carrier 30 is removed to expose the active surfaces 32a of the electronic elements 32 and then a circuit layer 34 and an RDL structure 35 are formed, as shown in FIG. 3E′. Thereafter, a singulation process is performed, as shown in FIG. 3F′.

According to the first embodiment of the present invention, the frame 31 and the carrier 30 are separately fabricated. The openings 310 of the frame 31 are formed through the mold 9. Therefore, as long as the frame pattern 91 meets the requirement, the size of the openings 310 can be accurately controlled so as not to form chamfers between the openings 310 and the carrier 30. On the other hand, even if a chamfer is formed at the bottom of the openings 310, the accuracy of the chamfer can be effectively controlled.

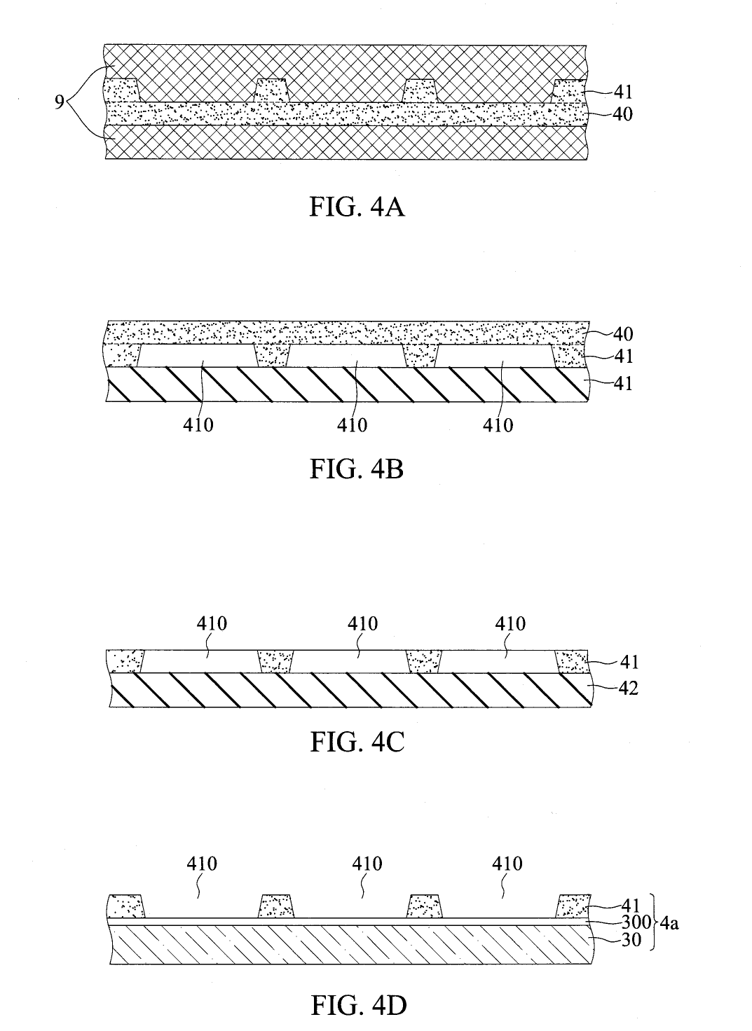

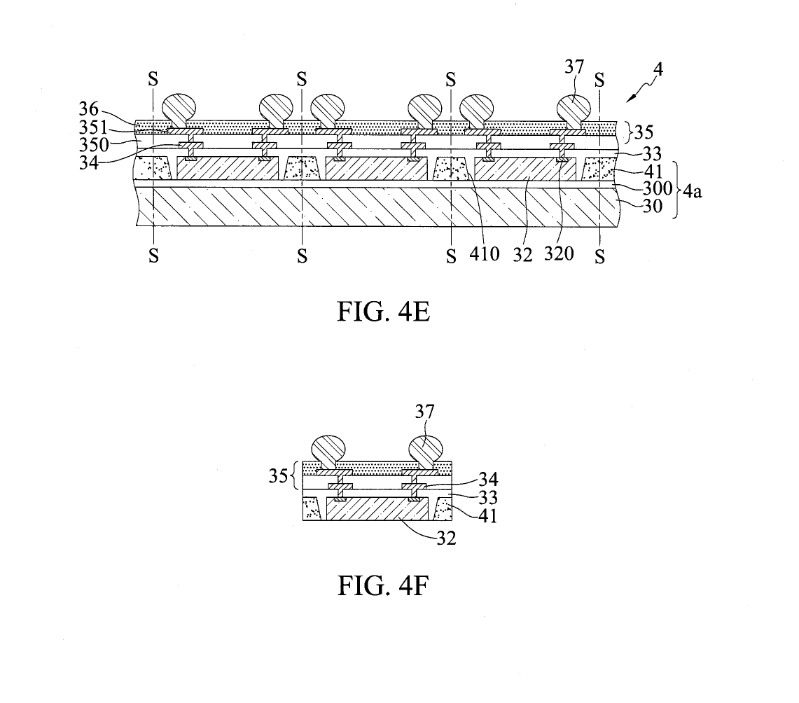

FIGS. 4A to 4F are schematic cross-sectional views showing a method for fabricating a semiconductor package 4 according to a second embodiment of the present invention. The present embodiment differs from the first embodiment in the process of forming the frame.

Referring to FIG. 4A, a dielectric material is filled in a mold 9 by molding so as to cause the dielectric material to form a frame 41 and a base portion 40 supporting the frame 41.

In the present embodiment, the dielectric material of the frame 41 and the base portion 40 is a molding compound.

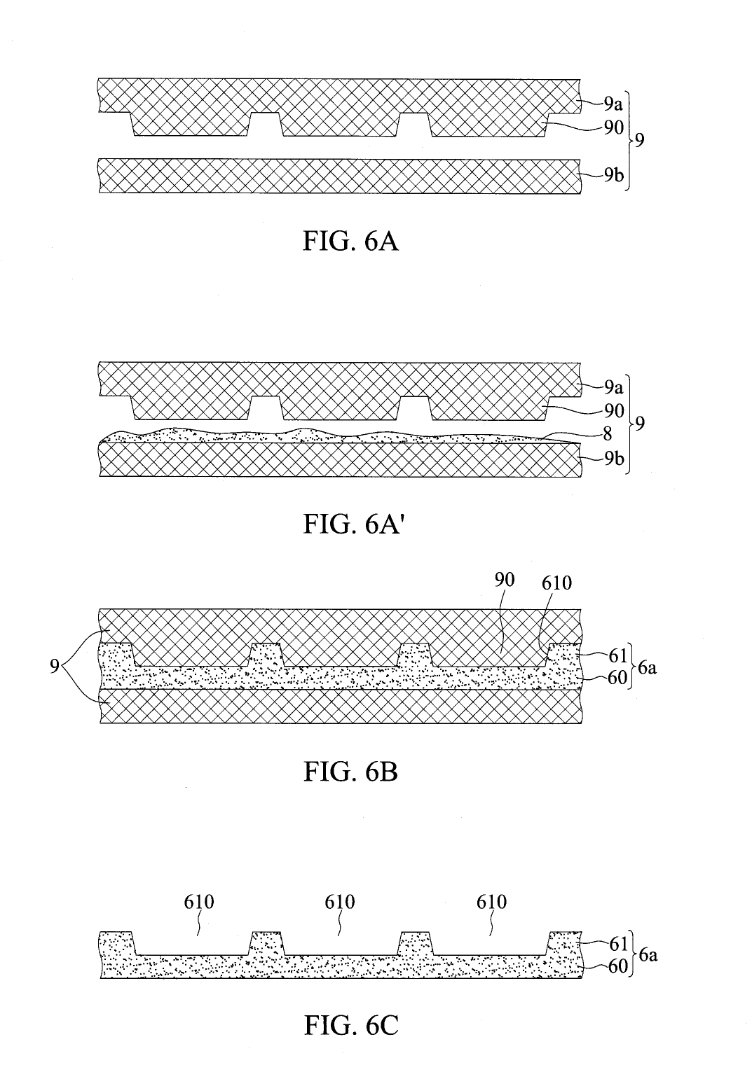

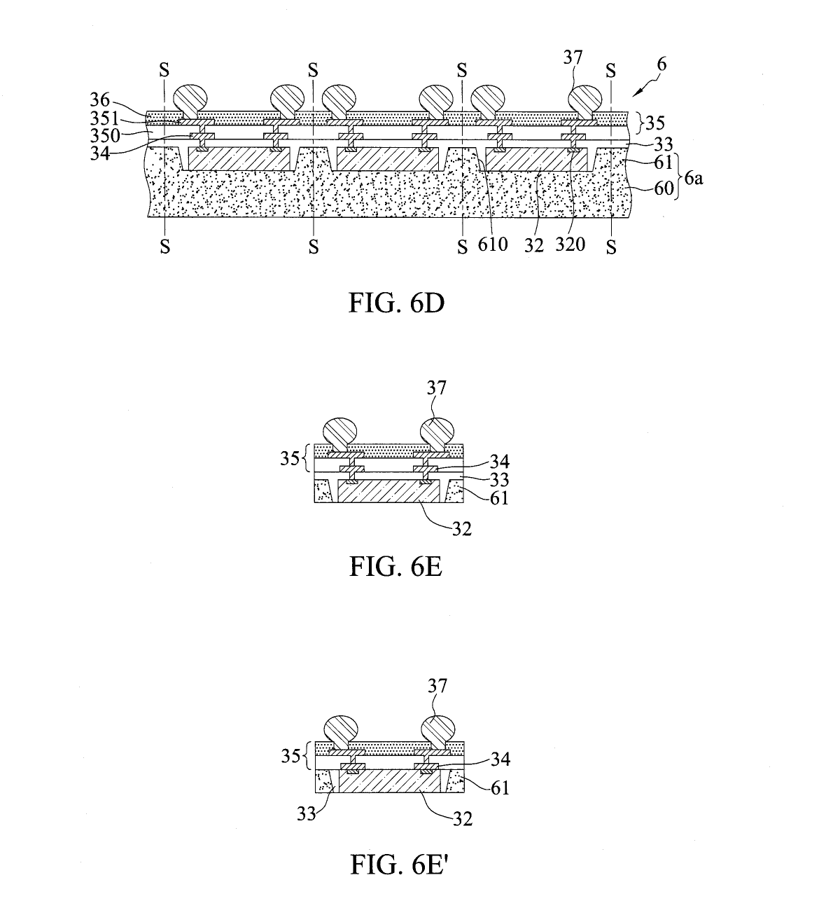

Further, the molding process can refer to the steps of FIGS. 6A′ and 6B (to be described later).

Referring to FIG. 4B, the mold 9 is removed. As such, the frame 41 is formed with a plurality of openings 410. Then, the frame 41 and the base portion 40 are disposed on a support member 42, with the openings 410 facing the support member 42.

Referring to FIG. 4C, the base portion 40 is removed by grinding or sandblasting.

Referring to FIG. 4D, the support member 42 is removed and then the frame 41 is bonded to a carrier 30. As such, the frame 41 having the openings 410 and the carrier 30 constitute a carrier structure 4a.

In the present embodiment, a bonding layer 300 is formed on the carrier 30 first and then the frame 41 is bonded to the bonding layer 300.

The bonding layer 300 can be a die attachment film. The bonding layer 300 can be formed by adhesive coating or chemical vapor deposition (CVD). Alternatively, the bonding layer 300 can be made of SiO₂ formed by thermal oxidation of a wafer fusion process.

Then, referring to FIGS. 4E and 4F, processes similar to those of FIGS. 3C to 3F (or FIGS. 3C′, 3E′ and 3F′) are performed. Referring to the drawings, a plurality of electronic elements 32 are disposed in the openings 410 on the bonding layer 300, respectively.

According to the second embodiment of the present invention, the frame 41 and the carrier 30 are separately fabricated. The openings 410 of the frame 41 are formed through the mold 9. Therefore, as long as the mold 9 meets the requirement, the size of the openings 410 can be accurately controlled so as not to form chamfers between the openings 410 and the carrier 30. On the other hand, even if a chamfer is formed at the bottom of the openings 410, the accuracy of the chamfer can be effectively controlled.

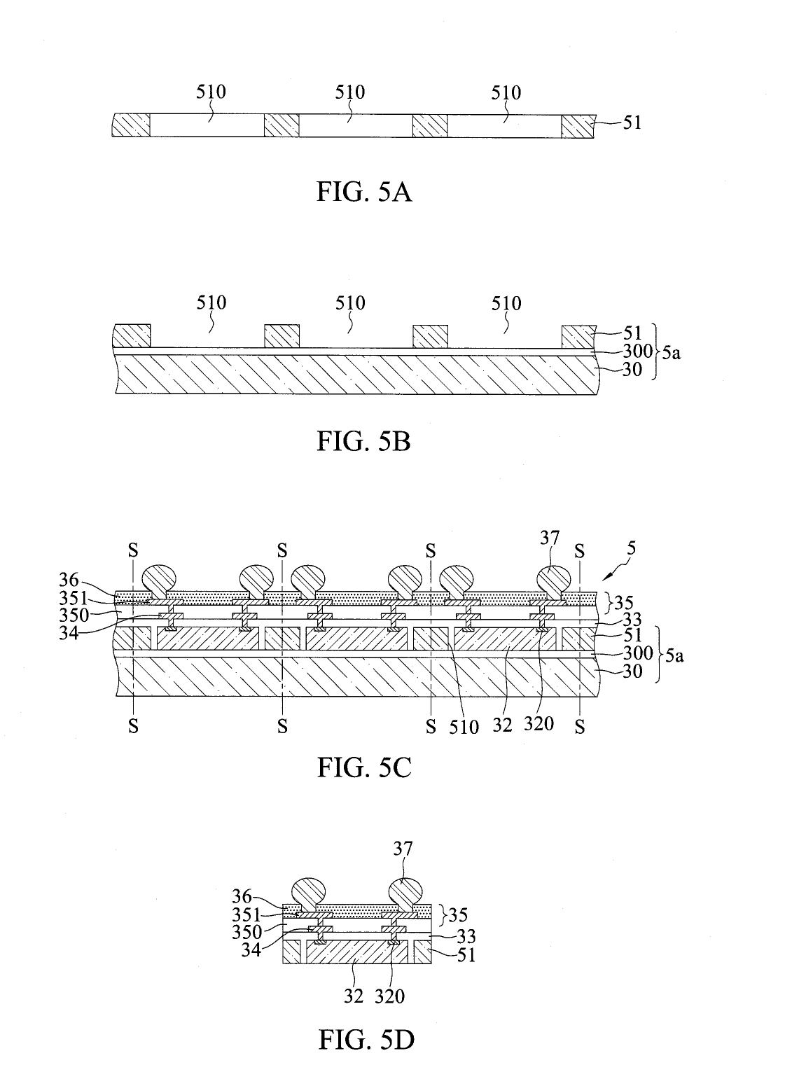

FIGS. 5A to 5D are schematic cross-sectional views showing a method for fabricating a semiconductor package 5 according to a third embodiment of the present invention. The present embodiment differs from the first embodiment in the process of forming the frame.

Referring to FIG. 5A, a semiconductor board is etched to form a frame 51 having a plurality of openings 510.

Referring to FIG. 5B, a bonding layer 300 is formed on a carrier 30 and the frame 51 is bonded to the bonding layer 300 of the carrier 31. The frame 51 having the openings 510, the bonding layer 300 and the carrier 30 constitute a carrier structure 5a.

Then, referring to FIGS. 5C and 5D, processes similar to those of FIGS. 3C to 3F (or FIGS. 3C′, 3E′ and 3F′) are performed.

According to the third embodiment of the present invention, the frame 51 and the carrier 30 are separately fabricated. Therefore, the size of the openings 510 is first determined to meet the requirement and then the frame 51 is disposed on the carrier 30 so as not to form chamfers between the openings 510 and the carrier 30. On the other hand, even if a chamfer is formed at the bottom of the openings 510, the accuracy of the chamfer can be effectively controlled.

FIGS. 6A to 6E are schematic cross-sectional views showing a method for fabricating a semiconductor package 6 according to a fourth embodiment of the present invention. The present embodiment differs from the first embodiment in the process of forming the carrier and the frame.

Referring to FIG. 6A, a mold 9 having a plurality of protruding portions 90 therein is provided. In the present embodiment, the mold 9 has a first mold body 9a and a second mold body 9b. The protruding portions 90 are formed on the first mold body 9a.

Referring to FIG. 6B, a dielectric material is filled in the mold 9 by molding so as to cause the dielectric material to form a carrier 60 and a frame 61. The carrier 60 and the frame 61 are integrally formed and a plurality of openings 610 are formed corresponding in position to the protruding portions 90 of the mold 9. The frame 61 having the openings 610 and the carrier 60 constitute a carrier structure 6a.

In another embodiment, referring to FIG. 6A′, a dielectric material 8 is formed on the second mold body 9b first and then the first mold body 9a and the second mold body 9b are pressed together so as to cause the dielectric material 8 to form the carrier 60 and the frame 61. The openings 610 are formed corresponding in position to the protruding portions 90.

Referring to FIG. 6C, the mold 9 is removed and the carrier structure 6a consisting of the frame 61 and the carrier 60 is provided.

In the present embodiment, the openings 610 have sloped sidewalls relative to the carrier 60. That is, the sidewalls of the openings 610 are sloped relative to the bottom surfaces of the openings 610.

Then, referring to FIGS. 6D and 6E, processes similar to those of FIGS. 3C to 3F (or FIGS. 3C′, 3E′ and 3F′) are performed.

According to the fourth embodiment of the present invention, the carrier 60 and the frame 61 are integrally formed. The openings 610 are formed through the mold 9. Therefore, as long as the protruding portions 90 are determined to meet the requirement, the size of the openings 610 can be accurately controlled so as not to form chamfers between the openings 610 and the carrier 60. On the other hand, even if a chamfer is formed at the bottom of the openings 610, the accuracy of the chamfer can be effectively controlled.

Further, in the first to fourth embodiments, if the encapsulant 33 is only formed in the openings 310, 410, 510, 610, the conductive vias can be dispensed with, as shown in FIG. 6E′.

The present invention further provides a semiconductor package 3, 4, which has: a carrier 30; a frame 31, 41 having a plurality of openings 310, 410, wherein the frame 31, 41 is bonded to the carrier 30; a plurality of electronic elements 32 disposed in the openings 310, 410 of the frame 31, 41, respectively; an encapsulant 33 formed in the openings 310. 410 of the frame 31, 41 for encapsulating the electronic elements 32; and a circuit layer 34 formed on and electrically connected to the electronic elements 32.

The carrier 30 can be made of an inorganic material or an organic material. The frame 31, 41 can be made of a material different from that of the carrier 30. For example, the frame 31, 41 is made of a dielectric material.

In an embodiment, the frame 41 is bonded to the carrier 30 through a bonding layer 300.

The present invention further provides a semiconductor package 5, which has: a carrier 30; a frame 51 having a plurality of openings 510, wherein the frame 51 is bonded to the carrier 30 through a bonding layer 300; a plurality of electronic elements 32 disposed in the openings 510 of the frame 51, respectively; an encapsulant 33 formed in the openings 510 of the frame 51 for encapsulating the electronic elements 32; and a circuit layer 34 formed on and electrically connected to the electronic elements 32.

The carrier 30 can be made of an inorganic material or an organic material. The frame 51 can be made of the same material as the carrier 30.

The present invention further provides a semiconductor package 6, which has: a carrier 60 made of a dielectric material; a frame 61 having a plurality of openings 610, wherein the frame is bonded to and integrally formed with the carrier 60; a plurality of electronic elements 32 disposed in the openings 610 of the frame 60, respectively; an encapsulant 33 formed in the openings 610 of the frame 60 for encapsulating the electronic elements 32; and a circuit layer 34 formed on and electrically connected to the electronic elements 32.

In an embodiment, the semiconductor package 3, 4, 5, 6 further has an RDL structure 35 formed on the electronic elements 32 and the circuit layer 34 and electrically connected to the circuit layer 34.

The present invention further provides a carrier structure 3a, 4a, which has: a carrier 30; and a frame 31, 41 having a plurality of openings 310, 410, wherein the frame 31, 41 is bonded to the carrier 30 and made of a material different from that of the carrier 30.

In an embodiment, the frame 41 is bonded to the carrier 30 through a bonding layer 300.

The present invention further provides a carrier structure 5a, which has: a carrier 30; and a frame 51 having a plurality of openings 510, wherein the frame 51 is bonded to the carrier 30 through a bonding layer 300 and made of the same material as the carrier 30.

In the above-described carrier structure 3a, 4a, 5a, the carrier 30 can be made of an inorganic material or an organic material.

The present invention further provides a carrier structure 6a, which has: a carrier 60 made of a dielectric material; and a frame 61 having a plurality of openings 610, wherein the frame 61 is bonded to and integrally formed with the carrier 60.

In an embodiment, the openings 610 have sloped sidewalls relative to the carrier 60.

In the above-described carrier structure 3a, 4a, 5a, 6a, the carrier 30, 60 can have a rectangular shape or a circular shape.

In the above-described carrier structure 3a, 4a, 5a, 6a, no chamfer is formed between the openings 310, 410, 510, 610 and the carrier 30, 60.

Therefore, by accurately controlling the size of the openings of the frame, the present invention increases the accuracy of positioning of the electronic elements and improves the surface integrity of the semiconductor package, thereby improving the product yield in subsequent processes.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a carrier;
a frame having a plurality of openings, wherein the frame is bonded to the carrier and made of a material different from that of the carrier;
a plurality of electronic elements disposed in the openings of the frame, respectively;
an encapsulant formed in the openings of the frame for encapsulating the electronic elements; and
a circuit layer formed on and electrically connected to the electronic elements.

2. The semiconductor package of claim 1, wherein the frame is made of a dielectric material.

3. The semiconductor package of claim 1, wherein the frame is bonded to the carrier through a bonding layer.

4. The semiconductor package of claim 1, wherein the carrier is made of an inorganic material or an organic material.

5. The semiconductor package of claim 1, wherein the carrier has a rectangular shape or a circular shape.

6. The semiconductor package of claim 1, wherein no chamfer is formed between the openings and the carrier.

7. The semiconductor package of claim 1, further comprising an RDL (redistribution layer) structure formed on the electronic elements and the circuit layer and electrically connected to the circuit layer.

8. A semiconductor package, comprising:
a carrier;
a frame having a plurality of openings, wherein the frame is bonded to the carrier through a bonding layer and the frame is made of the same material as the carrier;
a plurality of electronic elements disposed in the openings of the frame, respectively;
an encapsulant formed in the openings of the frame for encapsulating the electronic elements; and
a circuit layer formed on and electrically connected to the electronic elements.

9. The semiconductor package of claim 8, wherein the carrier is made of an inorganic material or an organic material.

10. The semiconductor package of claim 8, wherein the carrier has a rectangular shape or a circular shape.

11. The semiconductor package of claim 8, wherein no chamfer is formed between the openings and the carrier.

12. The semiconductor package of claim 8, further comprising an RDL structure formed on the electronic elements and the circuit layer and electrically connected to the circuit layer.

13. A semiconductor package, comprising:
a carrier made of a dielectric material;
a frame having a plurality of openings, wherein the frame is bonded to and integrally formed with the carrier;
a plurality of electronic elements disposed in the openings of the frame, respectively;
an encapsulant formed in the openings of the frame for encapsulating the electronic elements; and
a circuit layer formed on and electrically connected to the electronic elements.

14. The semiconductor package of claim 13, wherein the openings have sloped sidewalls relative to the carrier.

15. The semiconductor package of claim 13, wherein the carrier has a rectangular shape or a circular shape.

16. The semiconductor package of claim 13, wherein no chamfer is formed between the openings and the carrier.

17. The semiconductor package of claim 13, further comprising an RDL structure formed on the electronic elements and the circuit layer and electrically connected to the circuit layer.

18. A carrier structure, comprising:
a carrier; and
a frame having a plurality of openings, wherein the frame is bonded to the carrier and made of a material different from that of the carrier.

19. The carrier structure of claim 18, wherein the frame is bonded to the carrier through a bonding layer.

20. The carrier structure of claim 18, wherein the carrier is made of an inorganic material or an organic material.

21. The carrier structure of claim 18, wherein the carrier has a rectangular shape or a circular shape.

22. The carrier structure of claim 18, wherein no chamfer is formed between the openings and the carrier.

23. A carrier structure, comprising:
a carrier; and
a frame having a plurality of openings, wherein the frame is bonded to the carrier through a bonding layer and the frame is made of the same material as the carrier.

24. The carrier structure of claim 23, wherein the carrier is made of an inorganic material or an organic material.

25. The carrier structure of claim 23, wherein the carrier has a rectangular shape or a circular shape.

26. The carrier structure of claim 23, wherein no chamfer is formed between the openings and the carrier.

27. A carrier structure, comprising:
a carrier made of a dielectric material; and
a frame having a plurality of openings, wherein the frame is bonded to and integrally with the carrier.

28. The carrier structure of claim 27, wherein the openings have sloped sidewalls relative to the carrier.

29. The carrier structure of claim 27, wherein the carrier has a rectangular shape or a circular shape.

30. The carrier structure of claim 27, wherein no chamfer is formed between the openings and the carrier.
